(19) United States
(12) Patent Application Publication
(10) Pub. No.: US 2011/0220285 A1
(43) Pub. Date: Sep. 15, 2011

(54) METHODS AND SYSTEMS FOR TEXTURING CERAMIC COMPONENTS

(75) Inventors: Cheng-Tsin Lee, Union City, CA (US); Ho Ouk, Stockton, CA (US); Gary D. Harland, Fremont, CA (US); Edward Tomasek, Costa Mesa, CA (US)

(73) Assignee: MORGAN ADVANCED CERAMICS, INC., Hayward, CA (US)

(21) Appl. No.: 13/025,627

(22) Filed: Feb. 11, 2011

Related U.S. Application Data
(60) Provisional application No. 61/303,711, filed on Feb. 12, 2010.

(51) Int. Cl. B05D 7/00; C23C 16/44; C23F 1/08; H01L 21/00; B05D 1/02; B05D 1/28; B05D 3/02; C23C 4/08; C23C 4/10; C23C 26/00

(52) U.S. Cl. 156/345.1; 118/715; 427/372.2; 427/456; 427/454; 427/140

(57) ABSTRACT

Embodiments of the present invention provide methods for forming a hardened and roughened ceramic component. Specific steps include forming a sintered ceramic component, texturing the surface of the sintered ceramic component, and firing the component to harden it. The resulting ceramic component may have a textured surface, and in a specific embodiment, the textured surface has a roughness of about 100 to about 2000 μin Ra.

This application claims the benefit of U.S. Provisional Application Ser. No. 61/303,711, filed Feb. 12, 2010, titled “Method of Texturing Ceramic Reactor Components for Semiconductor Wafer Processing,” the entire contents of which are hereby incorporated by reference.

### FIELD OF THE INVENTION

Embodiments of the present invention relate generally to the manufacture and restoration of components used in semiconductor reactors, and in particular, to processes for providing a roughened surface on such a component that provides improved adhesion of metallized or other residue layers.

### BACKGROUND

Twin Wire Arc Spray (TWAS) aluminum (Al) and plasma sprayed ceramic films are commonly used to coat surfaces of semiconductor reactor components. These films increase component service life by increasing the surface roughness. During the TWAS process, pure Al is atomized with an electric arc made by the junction of two wires and transported to a substrate by an air jet. The wires are the source of the aluminum deposition. The plasma spray process is used to deposit Al, alumina, titania, yttria, and zirconia films using powdered raw materials and air or nitrogen as a propellant. FIG. 1 illustrates an example of a PVD Film/TWAS/Roughened Alumina stack arrangement.

In general, films such as TWAS provide surfaces that are rough (e.g., about 300 to about 1200 micro-inches Ra) (“Ra” is commonly defined as the arithmetic average roughness), and they are applied to a metal, ceramic or quartz substrate. Abrasive media blasting has been used to roughen chamber component surfaces as well. Because of the hardness of alumina ceramics, the roughness of the applied surfaces is usually limited to less than 100 μin (microinches) Ra when using abrasive media blasting. This low roughness limits TWAS and plasma spray film adhesion to ceramic surfaces. The roughened surfaces are used to capture deposition and process byproducts and residues for silica films deposited by CVD (“chemical vapor deposition”) or HDPCVD (“high density plasma enhanced chemical vapor deposition”), metal films deposited by PVD (“physical vapor deposition”) such as Al, Cu, Ta, TaN, Ti, TiN, Ni, W, and etch byproducts generated from wafer plasma cleaning and dry etching such as Al, silica, metal oxide, and polysilicon etch processes.

Rough surfaces enhance deposition (process product or byproduct) residue adhesion on plasma based reactor components by altering surface stresses, which in turn reduce debonding/buckling forces imposed on the surface. Holding more film residues leads to increased service life of the component inside the chamber. A rough surface reduces buckling forces by transforming tensile stresses that tend to pull off film residues, into shear forces. Since these residues are brittle in nature, they are stronger in shear than they are in tension. Compressive deposition products and byproducts can be found on components of CVD, PVD, or etch chambers. These components can be chamber shields, rings around the cathode where Si wafers are being coated, and/or process bell jars. Ring shaped components used around the wafer include deposition rings, clamp rings, and cover rings. FIGS. 2A to 2D show examples of such components.

More specifically, FIG. 2A shows an alumina dome, FIG. 2B shows a focus ring, FIG. 2C shows an edge ring, and FIG. 2D shows a side shield. The components are cleaned of deposited residues periodically when the deposits become too thick. Due to the compressive stress nature of these reactor residues, eventually interface stresses between the TWAS or plasma-sprayed material and the deposition (or component) surface can become high enough to lift the TWAS or plasma sprayed film off of the ceramic components. This results in spalling or compressive-stress driven film delamination of the residue and the rough bonding layer. Therefore, the adhesion of the rough surface film and/or process residue layer to the reactor component limits the service life of the reactor component.

Among the relevant requirements for long service life for the deposition or etch component are good acid corrosion resistance after multiple cleanings and high roughness for maximum process residue adhesion. The processes according to embodiments of the present invention provide acid resistant roughened alumina or zirconia reactor components having a textured surface that can increase both TWAS and process residue adhesion.

Adhesion of TWAS and plasma spray films to alumina components is generally weak chemically and predominantly mechanical in nature. Zirconia offers better TWAS adhesion because it is easier to roughen its surface by bead blasting. Zirconia is also advantageous because it has a chemical affinity for aluminum. One of the major concerns with TWAS is its adhesion to alumina. It is common practice to bead-blast hardened alumina and zirconia to provide texture. However, because of the high hardness of those materials, it is impossible to abrasively roughen such substrates to greater than 50 μin Ra without creating significant sub-surface damage. Even at a roughness of 50 μin Ra, some subsurface damage is created in the alumina.

During the bead blasting process, surface defects are also introduced in the alumina. Such defects cause particulate contamination during wafer processing and promote cohesive failures of the TWAS/alumina surface as film processing residues build up. One attempted solution to that problem has been to anneal the alumina after bead blasting. However, annealing cannot repair large sub-surface defects.

WO 2009/099461 discloses a process in which a green (i.e. unfired) ceramic reactor component is textured and then fired to densify and harden it. The description indicates that the manufacture of textured components with a roughness of up to 1000 μin is possible.

### BRIEF SUMMARY

Many disadvantages of the known methods and articles are resolved to a significant degree by the methods and articles described herein. In accordance with a first aspect of the present invention, there is provided a method of improving the adhesion of processing materials on a ceramic component. The method includes the steps of forming a sintered ceramic component and texturing the surface of the sintered ceramic component. The as-textured component is then fired to harden. The resulting ceramic component may have a textured surface formed thereon. In a specific embodiment, the textured surface has a roughness of about 100 to 2000 μin Ra.

In accordance with a second aspect of the present invention there is provided a further method of improving adhesion of processing materials on a ceramic component. The method includes the steps of forming a sintered ceramic reactor component and texturing the surface of the sintered ceramic reactor component. The as-textured component is then fired to densify and harden the texturing material. A coating such as TWAS may then be applied to the surface of the textured ceramic component to provide a secondary adhesion layer.

### BRIEF DESCRIPTION OF THE DRAWINGS

FIG. 1 is a schematic illustration of a partial cross section of a prior art layered component.

FIGS. 2A to 2D are schematic illustrations of prior art ceramic components used in semiconductor circuit processing chambers.

FIG. 2E shows a photograph of a ceramic component that has been processed according to one embodiment of the present invention.

FIG. 3 is a flow diagram of one embodiment of a process for texturing a ceramic.

FIG. 4 is a SEM photograph of a partial cross section of a ceramic component that was processed according to the steps of FIG. 3.

FIG. 5 is a plot of the green surface roughness measured with Laser Scanner against the number of passes in the texturing process as described in Example 1.

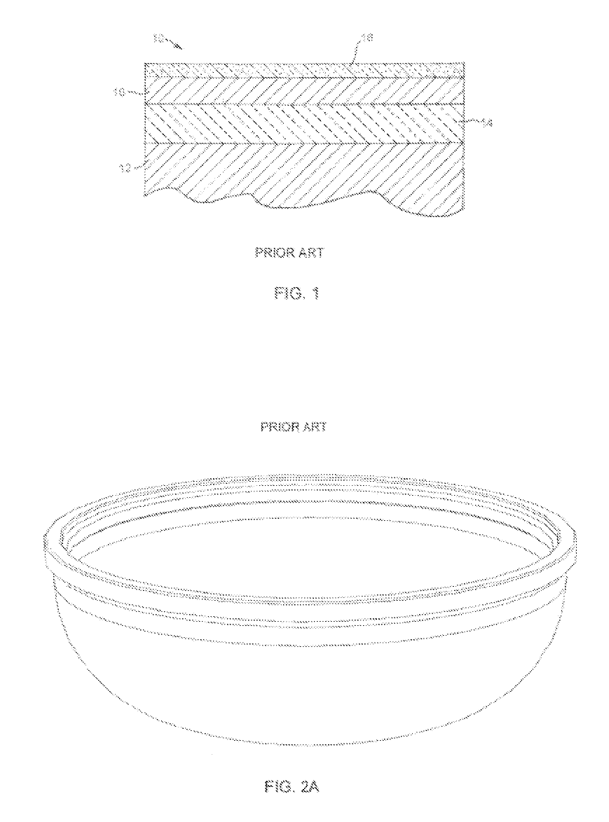

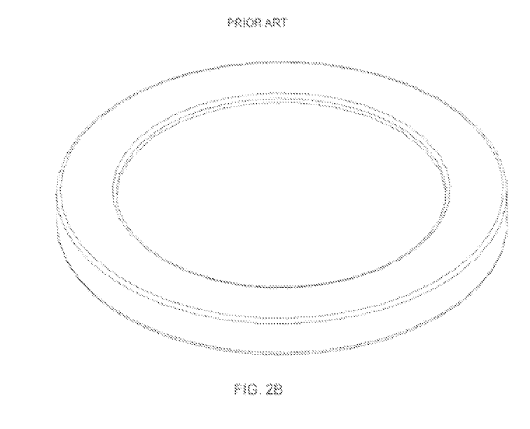

### DETAILED DESCRIPTION

Embodiments of the processes described herein permit the manufacturing of alumina and zirconia components (for example, domes, rings, shields, and any other appropriate components) with improved TWAS, plasma spray, and/or reactor process residue adhesion. Improving such adhesion is believed to help increase component service lifetimes. The TWAS/residue adhesion is improved by texturing the ceramic component surface while the ceramic is in the sintered state, i.e., after firing. This can be conducted with a spray coating of ceramic powder onto the sintered ceramic surface. The texture is then fired into the component and preserved for multiple component recycles because the ceramic material provides excellent acid corrosion resistance.

In comparison with bead blasting method, the methods described herein generally generate a higher roughness of the end product (e.g. Ra>1000 micro-inches). In addition, unlike bead blasting, the existence of subsurface micro cracks may be significantly lessened by using the described methods. Embodiments of the present invention may also be used to texture a semiconductor processing component that is currently in use. In addition to providing a higher roughness, embodiments may also repair subsurface micro cracks formed by previous bead blasting operations due to the high sintering temperature post-texturing.

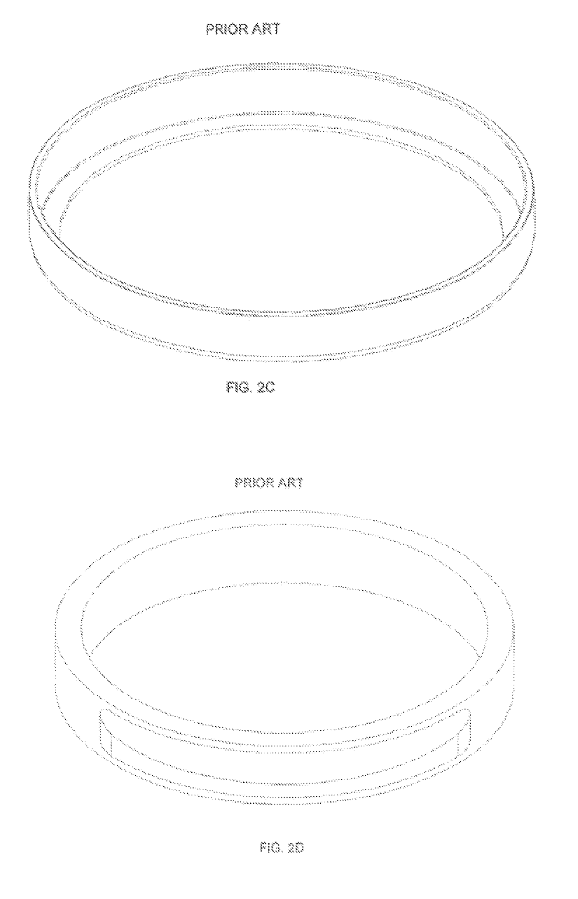

FIG. 3 illustrates a flow chart that shows one embodiment of a method for providing a roughened ceramic surface, and specifically, for providing a roughened surface on a reactor component. In a particularly specific embodiment, the ceramic component may be a semiconductor CVD, PVD, or Etch reactor component. In another particularly specific embodiment, the ceramic component may be a ring, dome, or shield used in a semiconductor reactor.

In Step 310, a ceramic powder is isostatically pressed to form a green compact in the general shape of the desired component. Isostatic pressing can be carried out using either a wet-bag or a dry-bag technique.

In Step 320, the green compact is machined to near net shape by a green machining technique, for example, using a numerical control machine with carbide tooling. In Step 321, the green ceramic is sintered to final or near final shape. In Step 330, the surface of the sintered ceramic shape is textured using any appropriate technique, particularly including any of the techniques described below. Hard or soft masking may be applied to areas of the sintered ceramic shape that do not require a textured surface.

In Step 340, the textured ceramic shape is sintered to final or near-final form. After firing, the component may be further machined and/or flattened to meet the precise geometric requirements for the particular process kit application, as indicated in Step 350. The ceramic-coated component can be used as-is or a metal layer may be applied, such as by TWAS or plasma spray, as indicated in Step 360. For example, after texturing and firing, the ceramic component may be coated by a secondary layer. In a first embodiment, the secondary layer may be a layer of TWIN Wire Arc sprayed aluminum. In another embodiment, the ceramic component may be coated by a plasma sprayed layer of aluminum, yttria, zirconia, hafnia, any combination thereof, or any other appropriate material. The textured component surface does not typically need to be blasted with an abrasive prior to TWAS or plasma spray coating. The fired-in textured surface is useful even without being coated for process residue accumulation in the reactor chamber.

In actual trials, it has been possible to produce alumina ring and shield surfaces with roughnesses exceeding 2000 μin Ra, and a range (peak to valley) exceeding 17000 μin as measured with a laser surface profilometer. Accordingly, embodiments described herein provide a ceramic component with a surface roughness of about 100 to about 2000 μin, and in specific embodiments exceeding 2000 μin. More specifically, roughnesses from about 500-800 μin may be obtained, roughnesses greater than about 500 μin may be obtained, roughnesses greater than about 1000 μin may be obtained, roughnesses greater than about 1500 μin may be obtained, or roughnesses greater than about 2000 μin may be obtained.

The texturizing step 330 may be carried out in a number of different ways. In a first embodiment, the sintered ceramic compact is textured by spraying a ceramic powder-based slip containing a ceramic powder and a binder. The ceramic powder may be a high purity alumina, magnesia, zirconia, yttria, any combination thereof, or any other appropriate ceramic powder. In a specific embodiment, the slip may be a thick slip or slurry of high purity alumina or zirconia powder mixed with an acrylic or polyvinyl alcohol (PVA) binder onto the surface of the sintered ceramic. A dispersant may be included in the slip or slurry in order to facilitate spraying. Alternatively, the texturing is applied by brushing a thin slip of a ceramic powder and binder mixture, for example an alumina/zirconia plus acrylic/PVA mixture, onto the surface of the sintered ceramic compact. Certain slip compositions may achieve higher roughnesses than others, and the components selected depend upon the end use of the product as well as customer and industry requirements.

In addition to the components that make up the slip used to texture the sintered ceramic, in certain embodiments in which a ceramic slip is sprayed (and not brushed) onto the sintered ceramic, it has been found that a higher roughness may be obtained by lowering the spray angle of the slip. For example, rather than using a steep or substantially normal spray angle (e.g., of 90° or an angle that is otherwise generally straight-on or head-on to the substrate), the spray may be angled at less than 45°, for example about 5 to about 25° to the substrate surface, in more specific embodiments, about 10 to about 20°, and in even more specific embodiments, about 10 to about 15° to the substrate surface. Steeper spray angles generally do not result in roughnesses as high as those provided by using lower spray angles. Roughnesses from about 2000 to about 3000 microinches may be obtained by using the lowered angles described.

It may also be desirable to conduct the texturing step while the substrate is warm or being warmed. For example, a hot plate or other warming surface may be used to heat the sintered ceramic component. Non limiting exemplary temperature ranges may be from about 60° C. to about 120° C., more specifically, from about 80° C. to about 100° C. Without wishing to be bound to any theory, it is believed that a higher substrate temperature may enhance the drying rate of the coating, which helps prevent overflow or migration of the slurry, with consequent smoothing of the surface.

When carrying out any of the foregoing texturing techniques, a mask may be applied to the sintered ceramic material so that only a selected area of the surface is textured. The mask may be a soft mask, such as tape or another flexible fabric applied to the surface of the sintered ceramic compact. Alternatively, a hard mask, for example, a plate or band made of metal or other hard material, can be positioned over the selected area.

Once the sintered ceramic has been textured, it is fired for a second time at a temperature sufficient to sinter the coating. This subsequent sintering helps densify and harden the component, as well as helps the rough coating/texturing obtain excellent adherence to the substrate. In other words, the slip coating is sintered to the substrate to provide a fired-in textured surface.

Customers in the semiconductor industry generally prefer roughnesses of about 500 microinches, which may be provided by the methods described herein, but particular customers or industry uses may call for higher roughness. Such enhanced roughnesses may be provided using the methods described herein. Additionally or alternatively, the components manufactured using the methods described herein may be subjected to a further treatment, such as TWAS or plasma spray coating.

The target adhesion strength for TWAS or reactor residues is equal to or greater than the tensile strength of annealed Al, typically about 10,000 to about 13,000 psi. Currently, TWAS adhesion to alumina is typically measured to be about 3,000 to about 5,000 psi using epoxy pull testing. Because of the chemical affinity of zirconia for Al, it is believed that TWAS adhesion to zirconia is approximately about 5,000 to about 7,000 psi. In actual experiments, TWAS peel strengths exceeding 10,000 psi were measured using samples prepared by the fired-in texturing process according to various embodiments of this invention. Sample surfaces made using the techniques described above typically provide peel strength of at least about 7,500 psi. Such high bond strength may increase reactor component service lifetimes, in some instances, by up to 300%, by reducing the frequency of periodic cleaning.

Alumina- and zirconia-coated reactor components such as domes, shields, and cover rings, featuring fired surfaces that have been textured in the sintered state could potentially hold thicker process residues than components having surfaces coated with TWAS or plasma spray films alone. The adhesion strength of such intermediate films would no longer be a factor in component life, thus eliminating a “weak link in the chain.” CVD, PVD, and etch chamber residues adhere well to ceramics, and it is possible that adhesion strength can exceed about 12,000 psi on an optimized surface.

Although the above describes manufacture from new, the present process, unlike that described in WO 2009/099461, may be used in the refurbishment of ceramic components. For example, a used semiconductor reactor component may have its surface cleaned and prepared (by any processes or combination of processes, for example such known processes as: grinding; lapping; chemical cleaning; plasma cleaning; bead blasting; sand blasting; and grit blasting) and a new textured surface applied, following by firing or sintering.

Specific embodiments are provided by the following non-limiting examples, which are provided for exemplary purposes only, and are not intended to limit this disclosure in any way:

### Example 1

In this specific example, the process of texturing the surface of sintered ceramic components starts with preparation of ceramic slurry. High purity alumina powder is mixed with 0.03 wt % Mg acetate sintering aid and 1% Darvan 821A dispersant in DI water (40%) and milled in a plastic jar with high purity alumina media for 2 hours to ensure proper dispersing of the fine alumina powder. In a specific embodiment, the high purity alumina powder may have a particle size distribution of about 0.5 μm to about 2.0 μm. After milling of the alumina powder, polymer binders and plasticizer such as PVA (2%) and PEG 400 (0.45%) will be added to the slurry and milled for one more hour. After milling, the slurry is filtered through a 1000 mesh nylon filter and poured into an industrial paint spray can. The source of texturing is an industrial paint spray gun operating at a pressures ranging from 20-60 psi, preferably 35 psi.

The texturing process is completed inside a well-ventilated industrial painting booth using commercially available automated equipment. In this example, the ceramic component is a 12″ diameter ceramic ring. The component is placed on a 26″ diameter industrial turntable. The turntable is turned on at 5-40 RPM, preferably about 10-20 RPM. A hot plate is used to heat up the ceramic ring to about 60° C. to about 120° C., preferably to about 80° C. to about 100° C. High substrate temperature will enhance the drying rate of the spray coating which helps prevent overflow of the slurry.

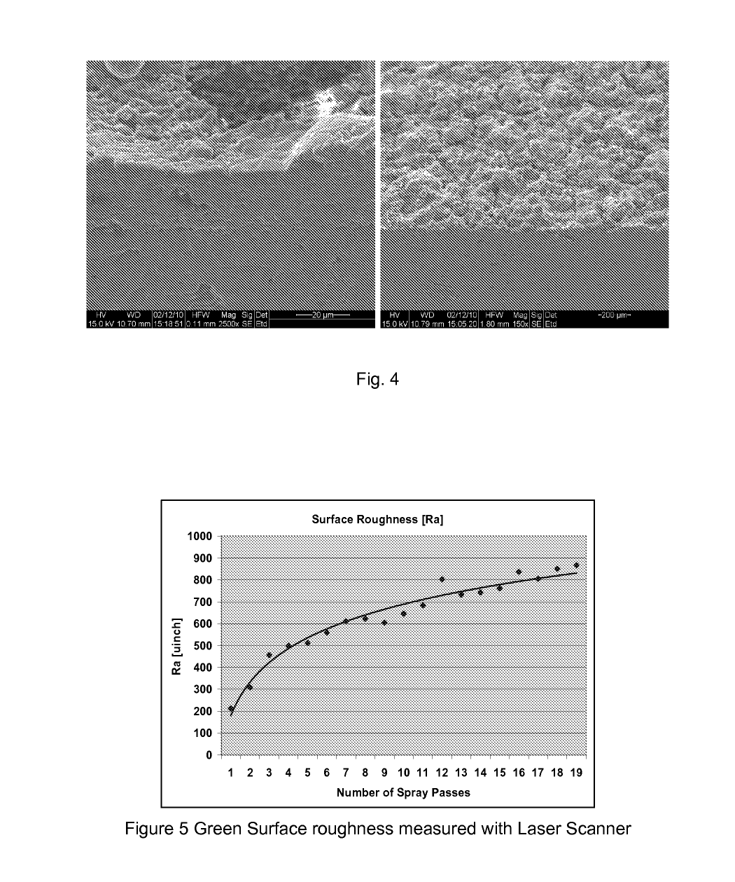

The spray gun is positioned about 4 to about 18 inches, preferably about 12 inches, above the application area to ensure uniform deposition over the ceramic ring. The angle of the spray gun may be about 5° to about 20° to obtain optimum roughness. The roughness of the spray coating is proportional to the number of passes of spraying, as illustrated by FIG. 5. Roughness (Ra) testing of the textured part is performed using a Cobra Laser Profile Scanner.

The textured ceramic component is then sintered at a temperature from about 1500° C. to about 1700° C. using an industrial gas furnace. After sintering, the surface roughness of the component can be characterized again using the laser profile scanner. As illustrated in Table 1, post-fired surface roughness ranges from about 150 to about 2000 microinch Ra and are proportional to the green surface roughness.

TABLE 1

| | # of | Ra by laser in | Ra by laser |
|---|---|---|---|
| Sample | passes | green | sintered |
| Sintered Al2O3 ring | 18 | 720 micro inches | 620 micro inches |
| 6″ sintered disk | 30 | 2700 micro inches | 2650 micro inches |

Although not required, an optional secondary coating of a metal layer may be applied to the textured ceramic components, such as TWAS or plasma spray, as indicated in step 360. In one embodiment, the textured, sintered ceramic is plasma sprayed with a film that contains primarily pure alumina, zirconia, or yttria. In a particular embodiment, the film may contain about 99% alumina, zirconia, or yttria.

The textured component surface does not need to be blasted with an abrasive prior to TWAS or plasma spray coating. Thus, the textured ceramic component can be used with or without the secondary coating for process residue accumulation in the reactor chamber.

### Example 2

Similar to the processing procedure illustrated in Example 1, a ZrO₂ based slurry may be prepared according the following formulation (Table 2):

TABLE 2

| | | |
|---|---|---|
| Material | Weight | Weight % |

| | | | |
|---|---|---|---|
| CS01 ZrO2 powder | 400 | g | |
| MgCO3 | 26 | g | 6.5% |
| Darvan 7 (dispersant) | 2 | g | 0.5% |
| DI water | 100 | g | 25% |
| PVA | 115 | g | 4.2% |
| Glycerol | 3 | g | 0.75% |

The zirconia (or other ceramic) powder may have a particle size distribution of about 0.5 μm to about 2.0 μm. After milling, the zirconia-based slurry is poured into the pressure can and sprayed over sintered zirconia and alumina coupons. The textured ceramic samples were sintered in an electric furnace at about 1640° C. for about 3 hours. The surface roughness of the textured ceramics in green and sintered state is listed in Table 3.

TABLE 3

| | # of | Ra by laser in | Ra by laser |
|---|---|---|---|
| Sample | passes | green | sintered |
| Sintered ZrO2 | 15 | 580 micro inches | 480 micro inches |
| coupons | | | |
| Sintered ZrO2 | 24 | 850 micro inches | 650 micro inches |
| coupon | | | |
| Sintered Al2O3 disk | 14 | 510 micro inches | 400 micro inches |

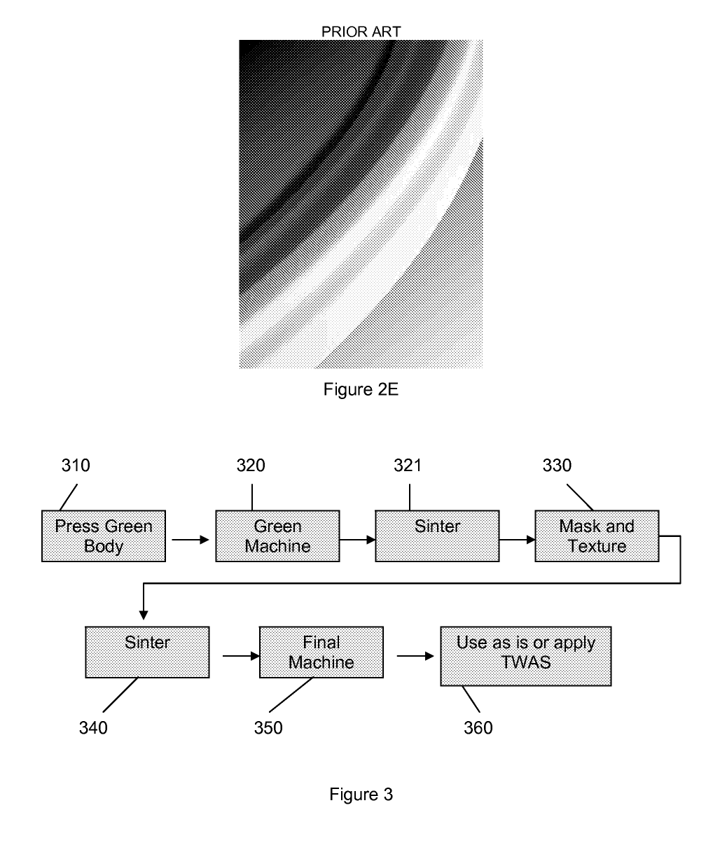

FIG. 4 is one example of an SEM photograph showing a cross-section of a textured ceramic manufactured according to the embodiments described herein. The interface between the substrate and the texturing material can be distinguished because since the grain size of the substrate is larger than that of the texturing ceramic. Some of the substrate grains grow into the texturing ceramic, suggest strong interfacial bonding between the textured coating and the substrate material.

Changes and modifications, additions and deletions may be made to the structures and methods recited above and shown in the drawings without departing from the scope or spirit of the invention and the following claims.

What is claimed is:

1. A method of improving adhesion of processing materials on a ceramic component, comprising:
(a) providing a sintered ceramic component;
(b) texturing the sintered ceramic component by applying a ceramic powder-based slip to provide an at least partially textured ceramic component; and
(c) firing the at least partially textured ceramic component to sinter the ceramic powder to the ceramic component.

2. The method according to claim 1, wherein (b) texturing the sintered ceramic component comprises applying a coating comprising a slip containing a ceramic powder and a binder.

3. The method according to claim 2, wherein applying a coating comprises spraying a surface of the sintered ceramic component with a thick slip containing the ceramic powder and the binder material.

4. The method according to claim 3, wherein the spraying is conducted at an angle of about 5° to about 20°.

5. The method according to claim 2, wherein applying a coating comprises brushing a surface of the sintered ceramic component with a thin slip containing the ceramic powder and the binder material.

6. The method according to claim 1, wherein the ceramic powder-based slip comprises high purity alumina, magnesia, zirconia, yttria, or any combination thereof.

7. The method according to claim 1, wherein (b) texturing the sintered ceramic component further comprises applying a mask to the sintered ceramic component before carrying out a texturing process.

8. The method according to claim 1, wherein after texturing and firing, the ceramic component is coated by a secondary layer.

9. The method according to claim 8, wherein the secondary layer comprises a layer of TWIN Wire Arc sprayed aluminum.

10. The method according to claim 1, wherein after texturing and firing, the ceramic component is coated by a plasma sprayed layer of aluminum, yttria, zirconia, hafnia, or any combination thereof.

11. The method according to claim 1, wherein after texturing and firing, the ceramic component has a surface roughness of about 100 to about 2000 μin.

12. The method according to claim 11, wherein the surface roughness is greater than about 500 μin.

13. The method according to claim 11, wherein the surface roughness is greater than about 1000 μin.

14. The method according to claim 11, wherein the surface roughness is greater than about 2000 μin.

15. The method according to claim 1, wherein the ceramic component is a semiconductor CVD, PVD, or Etch reactor component.

16. The method according to claim 1, wherein ceramic component is a ring, dome, or shield used in a semiconductor reactor.

17. The method according to claim 1, wherein the ceramic component is a sintered ceramic reactor component and wherein the method improves adhesion on a semiconductor ceramic reactor component.

18. The method according to claim 1, wherein (b) texturing the sintered ceramic component is conducted when the component is at a warmed temperature.

19. The method according to claim 18, wherein the temperature ranges from about 60° to about 120° Celsius.

20. The method according to claim 1, wherein the sintered ceramic component is a used ceramic component.

21. The method according to claim 20, wherein the used ceramic component has its surface cleaned and prepared prior to texturing step (b).

22. A semiconductor ceramic reactor component produced by the method of claim 1.
